(19) United States
(12) Patent Application Publication
(10) Pub. No.: US 2024/0201290 A1
(43) Pub. Date: Jun. 20, 2024

(54) LOCAL COILS WITH INTEGRATED EXCITATION FIELD SENSORS

(71) Applicant: Siemens Healthcare GmbH, Erlangen (DE)

(72) Inventor: Stephan Biber, Erlangen (DE)

(21) Appl. No.: 18/521,072

(22) Filed: Nov. 28, 2023

(30) Foreign Application Priority Data
Dec. 16, 2022 (EP) 22214182.2

(51) Int. Cl. G01R 33/34

(52) U.S. Cl. CPC G01R 33/34

(57) ABSTRACT

A local coil apparatus of a magnetic resonance system including a first sensor facility for detecting magnetic resonance signals. The local coil apparatus includes a second sensor facility for detecting an excitation signal of the magnetic resonance system. The excitation signal is configured for exciting the magnetic resonance signal by way of the magnetic resonance system.

### CROSS REFERENCE TO RELATED APPLICATIONS

This application claims the benefit of EP 22214182.2 filed on Dec. 16, 2022, which is hereby incorporated by reference in its entirety.

### FIELD

Embodiments relate to a local coil apparatus for a magnetic resonance system having a sensor facility for detecting magnetic resonance signals.

### BACKGROUND

In nuclear magnetic resonance, strong, radiofrequency fields are used to excite the spins in a patient's body. Fields in the range of up to 40 μT at frequencies of up to 300 MHz are generated by pulse amplifiers with several 10 kW of transmission power.

These transmission fields play an important role in image quality, since the time integral over the B1 amplitude defines the flip angle. If this is not distributed homogeneously throughout the image, undesirable differences in brightness or contrast may occur in the image that are difficult for the user to interpret. It is therefore desirable that the excitation or transmission field is distributed as homogeneously as possible in the patient. The homogeneity is limited by the hardware properties of the transmitter coil (usually body coil, or rarely local excitation coil, i.e., TX-LC), but possibly also by the interaction of the transmission field with the conductive tissue of the patient itself. Due to the increasing conductivity with increasing frequency, ever stronger eddy currents occur in the human body with increasing frequency, that make homogeneous excitation from the outside considerably more difficult and at 7 T (300 MHz) even require special measures (for example individually controllable transmitter coils) in order to achieve satisfactory homogenization.

The excitation or transmission fields of the body coils are also a potential hazard to the patient, since they cause the patient to heat up. The absorption of the transmission fields is measured by the unit SAR (specific absorption rate). There are standardized limit values for SAR that must be observed in order not to endanger patients. As a rule, relatively high safety margins are observed.

Nowadays, the transmission fields (in other words the radiofrequency excitation fields that are generated by a body coil) are monitored, for example, by monitoring the forward and backward wave to the two feed points of a circularly polarized antenna. In earlier systems, there were so-called pick-up coils in the body coil, that could measure the currents at selected bars of the body coil through a sample of the field in its immediate environment. For SAR monitoring, only four measured values are usually available (two measurements each for the forward and backward wave), that characterize the properties of the BC field generation (body coil). Only these values are also available for improving the homogeneity (by suitable selection of the excitation amplitudes and phases in systems with more than one transmission channel), or a real MR image must be recorded with a B1 field map in order to optimize the excitation amplitudes.

A method for field quality testing of a magnetic resonance antenna arrangement of a magnetic resonance system including a plurality of antenna elements is known from the publication DE 2008 026 849 B4. For some of the antenna elements suitable for receiving magnetic resonance signals, a noise signal and a test signal that is fed into the respective antenna elements by a transmitting antenna are each determined at a receiver unit. The noise signals and test signals are analyzed and a quality status of the magnetic resonance antenna arrangement is determined.

It has not been possible to measure RF transmission fields directly on the patient in order to use the relevant information to improve the above issues. Areas of improvement for which corresponding information would be helpful are, for example: improvement of SAR monitoring (it may be possible to further reduce safety margins that currently exist due to a very simple cylinder-human model and rough assumptions about the field distribution in order to increase the measurement speed), improvement of the image homogeneity, online monitoring of the transmission or TX field at various room points as an additional safety measure, and use of the transmission signal in lieu of a current pilot signal to detect patient movement and breathing, possibly even heartbeat.

Transmission fields may currently only be applied to the object to be examined, and their actual distribution may only be visualized in the (imaging) MR experiment, but not actually measured.

### BRIEF SUMMARY AND DESCRIPTION

The scope of the present disclosure is defined solely by the appended claims and is not affected to any degree by the statements within this summary. The present embodiments may obviate one or more of the drawbacks or limitations in the related art.

Embodiments are provided that detect a transmission field, in other words an excitation signal for exciting magnetic resonance signals in a simple manner in the examination area of a magnetic resonance system.

According to an embodiment, a local coil apparatus is accordingly provided for a magnetic resonance system. A magnetic resonance system may be configured as a magnetic resonance tomography unit. A local coil apparatus (called a local coil for short) is usually used to detect magnetic resonance signals directly on the object to be examined. For example, a local coil may be attached directly to a patient who is located in a patient tunnel of a magnetic resonance tomography unit. For example, specially shaped local coils may be arranged on the head, shoulder or knee of a patient in order to be able to detect magnetic resonance signals excited in these areas in a more targeted manner.

The local coil apparatus includes a first sensor facility for detecting magnetic resonance signals. The sensor facility may have as an actual sensor an antenna and in particular an antenna coil. Furthermore, the sensor facility may optionally also have an electronic unit for signal processing, in order to process signals of the antenna coil. Such an electronic unit may include, for example, an amplifier, a switch, a frequency multiplexer and many others. In each case, the first sensor facility is suitable for detecting very weak magnetic resonance signals and for forwarding them to a data processing unit of the magnetic resonance system.

The local coil apparatus includes a second sensor facility for detecting a (predetermined) excitation signal. The second sensor facility is different from the first sensor facility. In certain circumstances, the first sensor facility and the second sensor facility have the same hardware, but they are set differently, for example in terms of attenuation or amplification. The second sensor facility also includes an actual sensor such as an antenna or antenna coil. Naturally, similar to the first sensor facility, the second sensor facility may also have multiple sensors or antennas or antenna coils etc. Similar to the first sensor facility, the second sensor facility may also have an electronic unit in order, for example, to process signals of one or more antenna coils. The second sensor facility is configured to detect an excitation signal that is configured to excite the magnetic resonance signals, in other words to excite the nuclear spins whose precession in the magnetic field generates the magnetic resonance signals, by the magnetic resonance system. Excitation signals (magnetic transmission fields) and magnetic resonance signals (magnetic relaxation pulses) usually differ in amplitude by multiple orders of magnitude, for example 140 dB. This means that the first sensor device is generally suitable for detecting magnetic resonance signals, but not for detecting an excitation signal, at least not in the sense that the first sensor facility does not go into saturation and allows a quantitative evaluation of the excitation signal. Similarly, although the second sensor facility is suitable for detecting an excitation signal, it is not suitable for detecting a magnetic resonance signal, as this is below the noise limit. Thus, magnetic resonance signals are usually in a predetermined first signal strength range, while the excitation signal is usually in a second signal strength range that differs from the first.

In an advantageous manner, it is consequently possible using the local coil apparatus to also monitor TX or transmission fields directly locally on an object that is to be examined (for example patient). It is thus possible without a separate device in addition to a local coil to very precisely detect a transmission field directly on the patient.

The magnetic resonance system includes a local coil apparatus. The local coil apparatus is connected in terms of signaling to the transceiver unit via a signal output. The local coil apparatus transmits the detected magnetic resonance signal and the detected excitation signal via the signal output, in other words not simultaneously due to the temporal offset, but on the same path and using the same transmission system. The signal output and the transmission system is explained in more detail below.

The transceiver unit is configured so as to selectively evaluate a magnetic resonance signal and/or an excitation signal detected by the local coil facility. The local coil apparatus may be configured in such a manner that the transceiver unit may evaluate both the excitation signal and the magnetic resonance signal using the same receiver hardware. For example, amplitude ranges and frequency ranges of the signals of the local coil facility are selected so that both do not over-control a receiver of the transceiver unit and may be quantitatively analyzed. Adjustable filters and attenuators as well as algorithms may be set differently for the evaluation of both signals.

The local coil facility renders it possible using the same receivers of the transceiver unit to monitor both the excitation pulse and also to detect the magnetic resonance signals. It is thus possible without additional hardware to improve the safety and accuracy during the operation of the magnetic resonance scanner.

One embodiment provides that the first sensor facility and the second sensor facility jointly have (at least) one antenna coil, the first sensor facility includes a first electronic unit for processing the magnetic resonance signals that are detected by the antenna coil and the second sensor facility includes a second electronic unit, that is different from the first, for signal processing the detected excitation signal, and the local coil apparatus includes a switching facility with which the antenna coil may be switched alternately between the first or second electronic unit. This means that the first sensor facility and the second sensor facility overlap, the reason being that they include a common antenna coil. However, the first and the second sensor facility have different electronic units. Whereas the first electronic unit of the first sensor facility may process the very weak magnetic resonance signals, the second electronic unit of the second sensor facility may process the very strong excitation signals in particular corresponding detection signals of radiofrequency fields of powerful body coils. In this case, processing is to be understood to be not only binary processing, but (proportional) processing in dependence upon the respective signal strength. It is thus also possible to use the antenna coils of one local coil for detecting transmission fields. It is merely necessary to provide a suitable additional electronic unit in the local coil.

In an embodiment, the first electronic unit provides a lower attenuation or a higher amplification than the second electronic unit. A lower attenuation may be achieved, for example, by a lower impedance (alternating current resistance). Accordingly, the first electronic unit has a high coupling or a weak attenuation in comparison to the second electronic unit. As an alternative or in addition thereto, the first and the second electronic unit also each have an amplifier. The amplification of the first electronic unit with which the magnetic resonance signals or their detection signals are amplified has a higher amplification than the second electronic unit with which the already strong excitation signals or their detection signals are already processed. The second electronic unit may also have no amplification and possibly only attenuation.

In an embodiment, the first sensor facility includes (at least) one first antenna coil and the second sensor facility includes (at least) one second antenna coil that is different from the first antenna coil. In this case, therefore, one or more antenna coils are provided for detecting the magnetic resonance signals and one or more antenna coils are provided for detecting the excitation signals in the local coil apparatus. This has the advantage that the respective antenna coils may be configured specifically for the different signal strengths.

In an embodiment of this local coil apparatus, the first sensor facility and the second sensor facility include (at least in part) a common electronic unit for signal processing and a common signal output. The overlap between the sensor facilities in this case is therefore that only the electronic unit is used jointly, but each sensor facility includes their own antenna coils. In so doing, the different antenna coils may include different degrees of coupling into the electronic unit. The second sensor facility may be coupled in to a lesser extent or have a lower degree of coupling. In the case of the second sensor facility, it is possible to select higher detuning or higher attenuation between the antenna coils and the electronic unit than in the case of the first sensor facility. Due to the common electronic unit, there is also a common signal output. It is therefore not necessary to provide a separate signal output for detecting the excitation signal. Rather, the detection signals relating to the magnetic resonance signals and the excitation signals may be forwarded from the local coil apparatus to a further processing apparatus via a common signal output.

In an embodiment, the first antenna coil of the first sensor facility is arranged together with the second antenna coil of the second sensor facility on a common printed circuit board. In the same manner, it is also possible to arrange multiple antenna coils of the first sensor facility and multiple antenna coils of the second sensor facility on a common printed circuit board. This renders it possible not only to reduce production costs but it also makes it easy to determine the position of the respective antenna coils.

In an embodiment, the local coil apparatus may include a signal output path on which the first sensor facility and the second sensor facility may be switched via a (changeover) switch. Such a switch may be realized by a PIN diode or a transistor switch. Further electronic components may be provided upstream or downstream of the switch. The switch may be counted as part of the first and/or second electronic unit. The local coil apparatus may include an interface for an externally provided control signal. A control line from a central control unit of the magnetic resonance system to the local coil apparatus may be configured so as to control the switch according to the frequency of the transmission fields (excitation signals). In the transmitting phase, the second sensor facility should be switched on, whereas in the receiving phase, the first sensor facility should be switched on.

In an embodiment, all antenna coils of the first sensor facility and all antenna coils of the second sensor facility may be connected via a common frequency multiplexer to a common signal output path of the local coil apparatus. For example, the respective antenna coil signals at different frequencies are mixed and then superimposed to form a common signal. It is possible in this manner to transport outwards all detection signals of multiple antenna coils simultaneously via one line. Where appropriate, the signals of multiple antenna coils are subjected to different pre-processing before they are subjected to frequency multiplexing. In certain circumstances, frequency converters are also used to convert signals from the sensor facilities to respective intermediate frequencies so that the multiplex function may be used for both magnetic resonance signals (RX) and transmission signals (TX).

The signal connection from a signal output of the local coil apparatus to the MRT system may include a wired transmission system, an optical transmission system based on a waveguide or also a wireless transmission system by electromagnetic waves, for example radio waves between 1 MHz and 100 GHz or also in the infrared or optical frequency range. In this case, the signal connection may use an analogue or digital transmission system.

A local coil arrangement may also be provided with a local coil apparatus described above. Furthermore, the local coil arrangement includes an evaluation facility that is connected in terms of signaling to a local coil apparatus. The evaluation facility is therefore arranged outside the local coil apparatus. It is configured for the non-exclusively binary, quantitative determination of a signal strength of the excitation signal of the magnetic resonance system that is detected by the local coil apparatus within a predetermined signal strength range. The “non-exclusively binary determination” means that it is not only possible to establish whether a signal is present or not, but rather it is also possible to determine the signal strength in more than two stages continuously or rather quasi continuously. For example, it is thus possible to transmit a measurement signal to the evaluation facility. The signal strength of the measurement signal is proportional to the signal strength of the excitation signal or in another functional context. Consequently, the excitation signal may be accurately detected with respect to quantitative signal strength.

In the case of the local coil arrangement, the second sensor apparatus includes one or more antennas, and a respective relative position of each antenna within the local coil apparatus is provided for the evaluation facility so as to optimize a homogeneity of the excitation signal. Within the evaluation range of the local coil apparatus, it is consequently possible to readjust the excitation signal with respect to homogeneity. This is in particular possible because the respective antenna positions of the first sensor apparatus for detecting the excitation signal are known. Consequently, where appropriate, the evaluation facility may control the magnetic facility of the magnetic resonance system in such a manner that the excitation signal is homogenous in the detection range of the local coil apparatus.

In an embodiment, the local coil arrangement may be switched in a first state of detection using the first sensor facility and in a second state of detection using the second sensor facility. The evaluation facility is configured in such a manner that a resolution bandwidth of the evaluation facility is automatically parameterized in dependence upon the respective state. For example, a different resolution is required for detecting the magnetic resonance signals than for detecting the excitation signal. In this case, a switching signal that is used for switching the two sensor facilities may also be used for the purpose of switching over the resolution bandwidth of the evaluation facility accordingly. The appropriate resolution is consequently selected for each state.

A method for operating a local coil apparatus for a magnetic resonance system is also provided with the local coil apparatus equipped with a first sensor facility for detecting magnetic resonance signals, by detecting an excitation signal of the magnetic resonance system by a second sensor facility of the local coil, wherein the excitation signal is configured for exciting the magnetic resonance signals by the magnetic resonance system.

The advantages and development possibilities mentioned above in connection with the local coil apparatus or the local coil arrangement also apply mutatis mutandis for the method. In this case, the mentioned functional features are regarded as corresponding method steps.

For application cases or application situations that may arise during the method and that are not explicitly described here, it may be provided that an error message and/or a request for user feedback is output and/or a default setting and/or a predetermined initial state is set in accordance with the method.

### BRIEF DESCRIPTION OF THE FIGURES

FIG. 1 depicts a schematic view of a magnetic resonance system according to an embodiment.

FIG. 2 depicts a first embodiment of a local coil apparatus.

FIG. 3 depicts a second embodiment of a local coil apparatus.

FIG. 4 depicts a block flow diagram of a method according to an embodiment.

### DETAILED DESCRIPTION

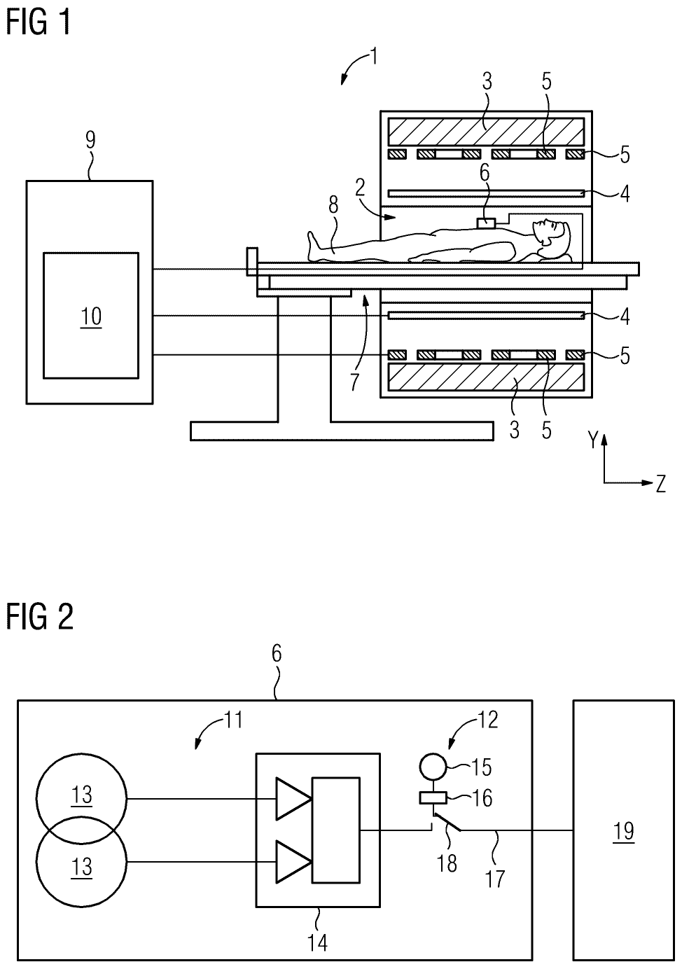

FIG. 1 depicts a schematic representation of an embodiment of an (MRT) system 1 (also referred to as a magnetic resonance system).

The MRT system 1 includes a magnet unit having a field magnet 3 that generates a static magnetic field to align nuclear spins of an object 8, for example a patient, in an imaging area. The imaging area is characterized by an extremely homogenous static magnetic field, wherein the homogeneity relates to the magnetic field strength or to its amplitude. The imaging area is located in a patient tunnel 2 that extends in a lengthwise direction Z through the magnet unit 10. The field magnet 3 may be, for example, a super-conductive magnet that may generate magnetic fields with a magnetic flux density of up to 3 T or more. However, it is also possible to use permanent magnets or electromagnets with normally conductive coils for lower field strengths. A patient table 7 may be movable within the patient tunnel 2.

Furthermore, the magnet unit includes a gradient coil arrangement 5 including multiple gradient coils that are used to superimpose on the static magnetic field gradient fields, in other words position-dependent magnetic fields, in the three spatial directions so as to spatially differentiate between the scanned image areas in the imaging area. The gradient coils of the gradient coil arrangement 5 may be configured, for example, as coils of normally conductive wires that may generate, for example, mutually orthogonal fields or field gradients in the imaging area.

The magnet unit includes a transmitter coil arrangement that may include, for example, a body coil 4 (also referred to as a whole body coil) as a transmitting antenna that is configured so as to emit a radiofrequency signal into the imaging area. The body coil 4 may therefore be understood as an RF transmitter coil arrangement of the MRT system 1 or as part of the RF transmitter coil arrangement. The body coil 4 may also be used in some embodiments so as to receive resonant MR signals that are emitted by the object 8. In this case, the body coil 4 may also be regarded as part of a signal detection apparatus of the MRT system 1. The signal detection apparatus may include a local coil apparatus 6 or a local coil apparatus that may be arranged in the immediate vicinity of the object 8, for example on the object 8 or in the patient table 7. The local coil apparatus 6 may be used as an alternative or in addition to the body coil 4 as a receiving coil or receiving antenna.

The local coil apparatus 6 is also provided with a sensor for detecting the excitation pulses that are emitted by the body coil 4.

The local coil apparatus 6 is connected in terms of signaling to the MRT system 1 via a signal output 17 in order to transmit the detected magnetic resonance signals and the detected excitation signals for further evaluation. The connection in terms of signaling may be a wired connection or a connection, for example, via one or multiple coaxial cables or twisted pair lines, optical wave conductors or also a wireless connection via a radio connection or optical transmission.

The MRT system 1 also includes a control and computing system 9. The control and computing system 9 may include a transceiver control unit 10 that is connected to the body coil 4, the gradient coil arrangement 5 and/or the local coil apparatus 6. In dependence upon the detected MR signals, the transceiver control unit 10, that may include an analog-to-digital converter, ADC may generate corresponding MR data, in particular in k-space. Where appropriate, the transceiver control unit 10 is also connected to the body coil 4 and controls it so as to generate RF pulses, such as excitation pulses and/or refocusing pulses. Furthermore, the transceiver control unit 10 of the control and computing system 9 may also be connected to the gradient coil arrangement 5 and control it in order to switch layer selection gradients, gradients for the frequency coding and/or phase coding and/or read-out gradients.

A radiofrequency sensor system is to be provided, for example, on the patient, the radiofrequency sensor system being suitable for receiving radiofrequency transmission fields and providing the information for improving the homogeneity or the SAR monitoring. Existing local coils are to be used for monitoring the transmission fields without their electronic system being over-controlled or even destroyed by the TX or transmitting pulses.

A TX field sensor system may be integrated in existing local coils or local coil apparatuses. During the transmitting phase, the local coils collect the field of the transmission pulse and deliver it to the receiver, as is normally the case during the receiving phase. This may digitalize the data and make it available to the magnetic resonance system for post-processing.

FIG. 2 depicts schematically an embodiment of a local coil apparatus 6. FIG. 2 includes a first sensor facility 11 and a second sensor facility 12. The first sensor facility 11 includes one or more antenna coils 13 for receiving RX or magnetic resonance signals. In the present case, the first sensor facility 11 includes two antenna coils 13. In addition, the first sensor facility 11 includes in this case a first electronic unit 14. Each of the two antenna coils 13 is connected to an input of the first electronic unit 14. The first electronic unit 14 may have amplifier elements in order to amplify the signals of the antenna coils 13. In addition, it may have a frequency multiplexer in order to combine the input signals to form a common output signal. It is also possible to also use other multiplex methods, such as time-multiplex, for such a combination.

The second sensor facility 12 includes in this case a second antenna coil 15. The second antenna coil 15 is connected by its signal output to an optional attenuating element 16. The second antenna coil 15 is used for detecting a TX or transmission field of the body coil 4. This signal may well have a difference of 140 dB compared to magnetic resonance signals. It may therefore be favorable to connect the attenuating element 16 downstream of the second antenna coil 15. The attenuating element 16 may be part of a second electronic unit of the second sensor facility. Where appropriate, it is the only component of the second electronic unit.

The local coil apparatus 6 includes in this case a common signal output 17. The first sensor facility 11 or the second sensor facility 12 or the first electronic unit 14 or the second electronic unit may be connected alternately to the common signal output 17 via a changeover switch 18. This means that all detection signals of the first antenna coils 13 and of the second antenna coil(s) 15 may be directed via the common signal output 17 to an evaluation facility 19. The evaluation facility 19 may be part of the magnetic resonance system 1.

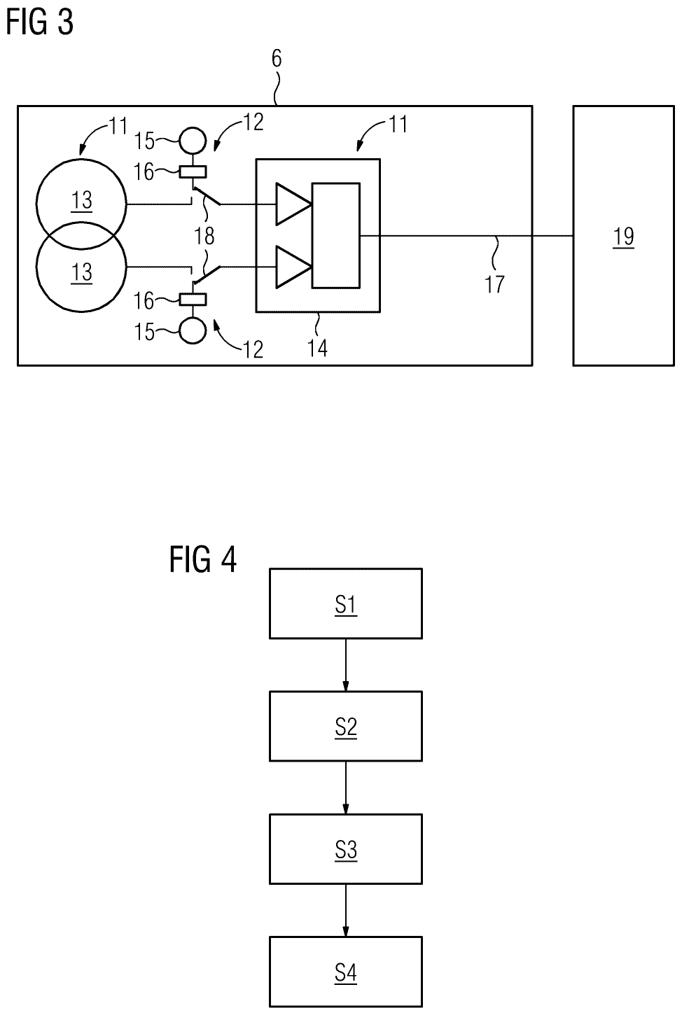

FIG. 3 depicts an embodiment of a local coil apparatus 6. It is constructed in a similar manner to the local coil apparatus 6 from FIG. 2. Only the differences are described below. The local coil apparatus 6 includes in this case two second antenna coils 15. Where appropriate, in this case, an attenuating element 16 is connected downstream of each second antenna coil 15. The (frequency) multiplexer of the first electronic unit 14 of the first sensor facility 11 also includes here in each case an input for each of the first antenna coils 13. In the present case, therefore two inputs. A changeover switch 18 is provided at each of the inputs respectively. It is possible using the respective changeover switch 18 either to connect the first antenna coil 13 or the second antenna coil 15 to the respective input of the (frequency) multiplexer. Each input of the multiplexer may consequently be used alternately for TX and RX detection.

The first electronic unit 14 may be understood here as a common electronic unit for both sensor facilities 11 and 12. The second sensor facilities 12 have in this case the additional attenuating elements 16 that may represent additional electronic units.

Since the second antenna coils 15, just as the first antenna coils 14, are located at the input of the multiplexer, multiple second antenna coils may also be used as first antenna coils. In contrast thereto, in the case of FIG. 2 only a single second antenna coil 15 may be used since in the exemplary embodiment shown it is connected to the output of the multiplexer.

Variation possibilities of the components of the local coil apparatus 6 for the RX and TX detection are described below. Similar to the case of FIG. 2, one or more second antenna coils 15 (TX sensors) may be introduced into the local coil apparatus 6 without an active electronic system. This may result in the following sub-variants:

The second antenna coils 15 are configured as dedicated small, non-resonant antennas (for example with a diameter of 1 to 50 mm). These may be mounted on a PCB board of a detuning electronic system or on a printed circuit board of the first electronic unit 14, or be made up of discrete components. This results in hardly any additional costs. The antenna coil 15 is connected to the TX detection path (signal output 17).

The existing first antenna coils 13 are also used to detect the transmission fields. For this purpose, the first antenna coils 13 (RX antenna) are only weakly coupled in the transmitting phase. Consequently, only a small part of the transmission signal, that induces current there, in order to send only a small signal part via the output path of the local coil apparatus 6. Separate second antenna coils 15 are not provided in this case. The first sensor facility and the second sensor facility therefore share the first antenna coils 13.

One or more attenuating elements (within the respective coil) between the first antenna coils 13 and the evaluation facility 19 are used to adapt signals and suppress standing wave effects.

It is therefore possible to install a sensor for the transmission field for each line to the local coil apparatus 6. In the case of two lines, it is possible to install two TX sensors accordingly.

Alternatively, the second antenna coils (TX sensors) may also be used with an active electronic system. A distinction may be made between the following cases:

The transmission field is picked up by the respective antenna coils in such a way that the first electronic unit for processing the detection signals of the magnetic resonance signals is not over-controlled. The detection signals for the transmission fields may thus be sent to the RX electronic system (first electronic unit 14). This electronic unit may include a mixer or a low noise converter. It is thus also possible to use the frequency multiplex function of the RD detection for the TX detection. Moreover, it is also possible to place multiple TX sensor elements, such as RX sensor elements, in the local coil apparatus.

The sensor signals may be switched over in the transmitting phase and the receiving phase by conventional switches, such as for example PIN diodes or transistor switches.

As shown in FIG. 2, the first antenna coils 13 (RX coils) may have a switch-over in the receiving path. This means that the cable that is used for the return delivery of RX signals may also be used for the return delivery of TX signals. This may be achieved in various ways:

As shown in FIG. 2, the switch 18 is installed between the first electronic unit 14 and the second antenna coil 15 for detecting the transmission field. Consequently, it is possible to switch between the two signal channels. The already existing PIN diode signal may be used as the switching signal.

Where appropriate, the TX detection signal may be coupled to the output line of the local coil apparatus (inductive, capacitive or resistive by virtue of a so-called power combiner). The TX detection element should then be configured in such a manner that in the transmitting phase there is always clearly crosstalk between the signal from the TX detection element and the signal from the RX path.

The components of the local coil apparatus must be calibrated in order to achieve accurate measurements. This is the only way that quantitative interpretations of the data are possible. It is possible to use a so-called “built-in-variant” for the calibration. The TX detection elements (second antenna coils 15) generally have an identical geometric construction so that they have identical amplitude sensitivity. The cable length from the TX detection element to the evaluation facility is relevant for the phase. Without the use of an active electronic system, the differences in cable length compared to the wave length are small and may be ignored.

An accurate calibration may be necessary if the accuracy of the above calibration is not sufficient or the signals are transmitted by the active electronic system. For example, a phase calibration of the TX detection elements and the RX chain behind them may be necessary for better utilization of the data. This may be done by prior phase calibration of the individual components and storage of the phases. Alternatively, an accurate calibration may be carried out by a so-called tune-up measurement under defined conditions for each local coil with TX detection elements located on it.

An exact geometric assignment of the TX detection elements is possible by describing their position in the coil housing of the local coil apparatus in corresponding metadata on the system. The position of non-fixed coils may be detected by various methods (for example using Hall sensors) in order to determine the current spatial position.

Since the post-processing of the data in the digital receiver depends upon how the data is to be used afterwards, it is also necessary to switch the digital receiver between the transmitting phase and the receiving phase. This may be parameterized with the parameters required by the corresponding application (for example SAR monitoring, motion detection, etc.) with regard to the resolution bandwidth of the data.

The subsequent applications may be based on a comparison of the individual TX detection signals with each other or on a comparison with the original TX pulses in order to be able to derive conclusions for further questions, for example regarding SAR, movement, etc. Parasitic fluctuations in the TX system, for example due to the heating of the transmitter or changes in the distance between the body coil and the gradient coil, may be compensated for by concurrently monitoring and subtracting these slow effects.

FIG. 4 depicts an embodiment of a method. The steps S1 to S3 are optional. In a first step S1, the local coil apparatus, for example, is switched in an RX detection mode. In a second step S2, magnetic resonance signals are detected by the first sensor facility 11 of the local coil apparatus. Subsequently, the local coil apparatus is switched into a TX detection mode according to step S3. Subsequently, according to step S4, the transmission field of the magnetic resonance system is detected by the second sensor facility 12 of the local coil apparatus 6.

Classic RX local coils are consequently supplemented by one or more TX detection elements for measuring the excitation field or transmission field in the proximity of the object or patient. Where appropriate, existing local coils may be retrofitted with such TX detection elements. The acquisition of TX field data may be used potentially for improving the SAR monitoring, for the movement detection or for improving patient safety and also for optimizing the image quality (B1 homogeneity).

Independent of the grammatical term usage, individuals with male, female or other gender identities are included within the term.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that the dependent claims may, alternatively, be made to depend in the alternative from any preceding or following claim, whether independent or dependent, and that such new combinations are to be understood as forming a part of the present specification.

While the present invention has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A local coil apparatus for a magnetic resonance system comprising:
a first sensor facility for detecting magnetic resonance signals; and
a second sensor facility for detecting an excitation signal of the magnetic resonance system;
wherein the excitation signal is configured for exciting nuclear spins that produce the magnetic resonance signals by way of the magnetic resonance system.

2. The local coil apparatus of claim 1, wherein the first sensor facility and the second sensor facility jointly share at least one antenna coil, the first sensor facility includes a first electronic unit for processing the magnetic resonance signals that are detected by the antenna coil and the second sensor facility includes a second electronic unit that is different from the first electronic unit for signal processing the detected excitation signal, and the local coil apparatus includes a switching facility with which the antenna coil may be switched alternately between the first or second sensor facility.

3. The local coil apparatus of claim 2, wherein the first electronic unit provides a lower attenuation or a higher amplification than the second electronic unit.

4. The local coil apparatus of claim 1, wherein the first sensor facility includes a first antenna coil and the second sensor facility includes a second antenna coil that is different from the first antenna coil.

5. The local coil apparatus of claim 4, wherein the first sensor facility and the second sensor facility include a common electronic unit for signal processing and a common signal output.

6. The local coil apparatus of claim 4, wherein the first antenna coil of the first sensor facility is arranged together with the second antenna coil of the second sensor facility on a common printed circuit board.

7. The local coil apparatus of claim 4, further comprising a signal output path, wherein the first sensor facility and the second sensor facility may be switched via a switch on the signal output path.

8. The local coil apparatus of claim 1, wherein all antenna coils of the first sensor facility and all antenna coils of the second sensor facility are switched via a common frequency multiplexer on a common signal output path of the local coil apparatus.

9. The local coil apparatus of claim 1, wherein an evaluation facility is connected in terms of signaling to the local coil apparatus and is configured for a non-exclusively binary, quantitative determination of a signal strength of the excitation signal of the magnetic resonance system that is detected by the local coil apparatus within a predetermined signal strength range.

10. The local coil apparatus of claim 9, wherein the second sensor facility includes one or more antennas, and a respective relative position of each antenna within the local coil apparatus is provided for the evaluation facility so as to optimize homogeneity of the excitation signal.

11. The local coil apparatus of claim 9, which in a first state of detection using the first sensor facility and in a second state of detection using the second sensor facility, wherein the evaluation facility is configured so that a resolution bandwidth of the evaluation facility is automatically parameterized in dependence upon the respective state.

12. A method for operating a local coil apparatus for a magnetic resonance system that includes a first sensor facility for detecting magnetic resonance signals, the method comprising:
detecting an excitation signal of the magnetic resonance system by a second sensor facility of the local coil apparatus;
wherein the excitation signal is configured for exciting nuclear spins that produce the magnetic resonance signals by way of the magnetic resonance system.

13. A magnetic resonance system comprising:
a local coil apparatus comprising:
a first sensor facility for detecting magnetic resonance signals; and
a second sensor facility for detecting an excitation signal of the magnetic resonance system, wherein the excitation signal is configured to excite nuclear spins that produce the magnetic resonance signals by way of the magnetic resonance system; and
a transceiver unit that is connected in terms of signaling via a signal output path to the local coil apparatus, wherein the transceiver unit is configured to selectively evaluate a magnetic resonance signal, an excitation signal, or the magnetic resonance signal and the excitation signal detected by the local coil apparatus.

14. The magnetic resonance system of claim 13, wherein the first sensor facility and the second sensor facility jointly share at least one antenna coil, the first sensor facility includes a first electronic unit for processing the magnetic resonance signals that are detected by the antenna coil and the second sensor facility includes a second electronic unit that is different from the first electronic unit for signal processing the detected excitation signal, and the local coil apparatus includes a switching facility with which the antenna coil may be switched alternately between the first or second sensor facility.

15. The magnetic resonance system of claim 14, wherein the first electronic unit provides a lower attenuation or a higher amplification than the second electronic unit.

16. The magnetic resonance system of claim 13, wherein the first sensor facility includes a first antenna coil and the second sensor facility includes a second antenna coil that is different from the first antenna coil.

17. The magnetic resonance system of claim 16, wherein the first sensor facility and the second sensor facility include a common electronic unit for signal processing and a common signal output.

18. The magnetic resonance system of claim 16, wherein the first antenna coil of the first sensor facility is arranged together with the second antenna coil of the second sensor facility on a common printed circuit board.

19. The magnetic resonance system of claim 16, further comprising a signal output path, wherein the first sensor facility and the second sensor facility are configured to be switched via a switch on the signal output path.

20. The magnetic resonance system of claim 13, wherein all antenna coils of the first sensor facility and all antenna coils of the second sensor facility are switched via a common frequency multiplexer on a common signal output path of the local coil apparatus.
